(19) United States
(12) Patent Application Publication
(10) Pub. No.: US 2024/0070346 A1
(43) Pub. Date: Feb. 29, 2024

(54) SELECTING WELLS FOR UNDERBALANCED COILED TUBING DRILLING IN DEEP AND TIGHT GAS RESERVOIRS

(71) Applicant: Saudi Arabian Oil Company, Dhahran (SA)

(72) Inventors: Kaiming Xia, Dhahran (SA); Yanhui Han, Houston, TX (US); Tariq Mahmood, Dhahran (SA); Kausik Saikia, Dhahran (SA); Weihua Wang, Dhahran (SA); Saidi Ali Hassani, Dhahran (SA)

(21) Appl. No.: 17/900,396

(22) Filed: Aug. 31, 2022

(51) Int. Cl. G06F 30/20; E21B 41/00; E21B 47/002

(52) U.S. Cl. CPC G06F 30/20; E21B 41/00; E21B 47/002; E21B 43/26; E21B 2200/20

(57) ABSTRACT

Systems and methods include techniques for determining whether to use underbalanced coiled tubing drilling (UBCTD) or conventional drilling with hydraulic fracturing to drill a new well in deep and tight reservoirs with slow rate of penetration issues. Estimates of geomechanical properties and image log processing for past-drilled wells are completed first, then three-dimensional (3D) property modeling and natural fracture prediction (NFP) for the domain are conducted. Then a 3D geomechanics model is generated. After this the rock properties and NFP along the planned well trajectory are extracted. The diagenetic rock typing is evaluated. Required breakdown pressure for hydraulic fracturing is calculated. A determination based on the diagenetic rock typing and required breakdown pressure is made whether UBCTD or conventional drilling with hydraulic fracturing should be used for a new well. Actions on evaluating whether NFP along the final well trajectory shear slip or any necessary stimulation are also discussed.

### TECHNICAL FIELD

The present disclosure applies to making decisions in drilling, such as for oil and gas wells in deep and tight formations.

### BACKGROUND

Drilling horizontal wells in deep seated and tight gas reservoirs can be very challenging, as slow rates of penetration can occur, and drilling bits can undergo fast abrasive wear. Generally, horizontal wells in deep and tight gas reservoirs are fractured for better well productivity. However hydraulic fracturing can fail at the beginning if the perforations require a high breakdown pressure to initiate fractures. In this case, underbalanced coiled tubing drilling (UBCTD) might be a good choice if the reservoir rock has good porosity and permeability, which can produce naturally after drilling. UBCTD allows for continuous drilling and pumping, which can increase the rate of penetration and avoid pipe differential sticking. UBCTD can also minimize formation damage and increase production. For underbalanced drilling, the pressure in the wellbore is lower than the pore pressure of the formation being drilled. To alleviate borehole breakout issues, the well should be drilled at an optimal direction, which requires a minimum mud weight. For UBCTD wells, generally, no hydraulic fracturing treatment is required to stimulate the well after the well is drilled. For this reason, UBCTD can be a good choice for certain reservoirs such as carbonate and sandstone, which have natural fractures and relatively larger permeability than that of shale. The well can produce naturally without stimulations like hydraulic fracturing treatment after drilling.

Hydraulic fracturing has been a technology key to facilitating economic recovery of natural gas/oil from tight formations. Hydraulic fracturing treatments are designed to stimulate production from tight reservoirs with low permeability, such as in shale or sandstone. However, hydraulic fracturing treatments can fail if the required breakdown pressures are higher than the wellhead can safely provide. In this situation, underbalanced coiled tubing drilling can be a good option if the rock porosity and permeability are reasonably good and conventional drilling has a slow rate of penetration issue. Full exploitation of coiled tubing drilling systems dictates that a practical approach should be taken. Because of the structural flexibility of coiled tubing, it is subject to limitations with respect to force transferring and the inability to rotate, and the application of this emerging technology needs to be directed to a niche where it provides the best value.

As is common for UBCTD horizontal wells, some wells can produce naturally while others cannot produce. For this reason, good processes are needed for screening whether a UBCTD is suitable for a well and to guide the actions or procedures that should be taken after UBCTD.

### SUMMARY

The present disclosure describes techniques that can be used for determining whether underbalanced coiled tubing drilling or conventional drilling with hydraulic fracturing is to be used in a drilling operation of a new well. In some implementations, a computer-implemented method includes the following. Estimates of geomechanical properties for past-drilled wells are determined using planned well trajectories, formation tops, and well logs from the past-drilled wells. Image log processing is performed for the past-drilled wells using the planned well trajectories, the formation tops, and the well logs for the past-drilled wells. Three-dimensional (3D) property modeling of the past-drilled wells is performed using the estimates of geomechanical properties for the past-drilled wells. Natural fracture prediction (NFP) for the past-drilled wells is performed based at least on the image log processing. A 3D geomechanics model is generated using the 3D property modeling of the past-drilled wells and the NFP for the past-drilled wells. The NFP is contained in the 3D geomechanics model for hydraulic fracturing modeling and fracture stability analysis. A required breakdown pressure for a clustered-perforation hydraulic fracturing treatment for a new well is determined using the 3D geomechanics model. A determination is made whether underbalanced coiled tubing drilling or conventional drilling with hydraulic fracturing is to be used in a drilling operation of the new well. The determination is made using the required breakdown pressure for the clustered-perforation hydraulic fracturing treatment for the new well.

The previously described implementation is implementable using a computer-implemented method; a non-transitory, computer-readable medium storing computer-readable instructions to perform the computer-implemented method; and a computer-implemented system including a computer memory interoperably coupled with a hardware processor configured to perform the computer-implemented method, the instructions stored on the non-transitory, computer-readable medium.

The subject matter described in this specification can be implemented in particular implementations, so as to realize one or more of the following advantages.

The techniques can help in determining whether a well should be drilled with underbalanced coiled tubing drilling. Use of the techniques can also avoid any uncertainties related to underbalanced coiled tubing drilled wells, especially with production performance. Actions can be taken to boost production rates. Since the techniques are developed based on field practice, the techniques can prevent the use of blind, trial-and-error methods which may waste a lot of time and money.

The details of one or more implementations of the subject matter of this specification are set forth in the Detailed Description, the accompanying drawings, and the claims. Other features, aspects, and advantages of the subject matter will become apparent from the Detailed Description, the claims, and the accompanying drawings.

### DESCRIPTION OF DRAWINGS

FIG. 1 is a flow diagram of an example of an integrated workflow for determining whether a well should be drilled with conventional drilling or underbalanced coiled tubing drilling (UBCTD), according to some implementations of the present disclosure.

FIG. 2 is a flow diagram of an example of an integrated workflow for actions and procedures to be followed after a UBCTD well is drilled, according to some implementations of the present disclosure.

FIG. 3 is a diagram showing a log-plot including formation image log processing and interpretation, according to some implementations of the present disclosure.

FIG. 4 is a diagram showing an example plot including natural fractures along the well trajectory, according to some implementations of the present disclosure.

FIG. 5 is a diagram showing an example model of a predicted discrete fracture network 500, according to some implementations of the present disclosure.

FIG. 6 is a diagram showing an example of a depth chart including rock porosity, total clay content, water content, and rock quality typing.

FIG. 7 shows an example of a finite element model for simulating the wellbore stress changes due to drilling rock fragmentation, according to some implementations of the present disclosure.

FIG. 8 is a diagram showing an example of a modeling stage diagram for predicting stress changes due to drilling rock fragmentation, according to some implementations of the present disclosure.

FIGS. 9A and 9B are diagrams showing examples of in-situ stresses after drilling rock fragmentation, according to some implementations of the present disclosure.

FIGS. 10A and 10B illustrate example effects of Coulomb stress change and shear strength, according to some implementations of the present disclosure.

FIG. 11 is a diagram showing an example of a depth chart illustrating a natural fracture stability analysis, according to some implementations of the present disclosure.

FIG. 12 is a diagram of an example of a plot showing hydraulic fractures propagating in a naturally fractured reservoir, according to some implementations of the present disclosure.

FIG. 13 is a flowchart of an example of a method for determining whether underbalanced coiled tubing drilling or conventional drilling with hydraulic fracturing is to be used in a drilling operation of a new well.

FIG. 14 is a block diagram illustrating an example computer system used to provide computational functionalities associated with described algorithms, methods, functions, processes, flows, and procedures as described in the present disclosure, according to some implementations of the present disclosure.

Like reference numbers and designations in the various drawings indicate like elements.

### DETAILED DESCRIPTION

The following detailed description describes techniques for determining whether underbalanced coiled tubing drilling or conventional drilling with hydraulic fracturing is to be used in a drilling operation of a new well. Various modifications, alterations, and permutations of the disclosed implementations can be made and will be readily apparent to those of ordinary skill in the art, and the general principles defined may be applied to other implementations and applications, without departing from the scope of the disclosure. In some instances, details unnecessary to obtain an understanding of the described subject matter may be omitted so as to not obscure one or more described implementations with unnecessary detail and inasmuch as such details are within the skill of one of ordinary skill in the art. The present disclosure is not intended to be limited to the described or illustrated implementations, but to be accorded the widest scope consistent with the described principles and features.

The question is how to determine whether underbalanced coiled tubing drilling (UBCTD) should be used for a well before drilling. To answer this question, the systems and methods for selecting underbalanced coiled tubing drilling are developed in the present disclosure. Specifically, in-situ stress changes due to drilling rock fragmentation are calculated, which is rarely considered in the oil and gas industry in current practices. In-situ stress changes are updated. A check is made whether any natural fractures along the wellbore will shear slip and increase stimulated rock volume. Based on this plus rock porosity and permeability, a determination can be made whether UBCTD should be a good option for drilling a well in a specific reservoir. In case the well cannot produce naturally after drilling, the required breakdown pressure can also be calculated. Pump schedules can be optimized based on hydraulic fracturing modeling, which can account for interactions between hydraulic fractures and discrete natural fractures. The workflow and procedures provided in this disclosure can be used to determine whether a well should be drilled with underbalanced coiled tubing drilling. Actions or procedures to be taken after drilling can also be identified.

The present disclosure describes two workflows related to underbalanced coiled tubing drilling. The first workflow can be used for determining whether a well should be drilled with underbalanced coiled tubing drilling in deep and tight gas reservoirs. Criteria used in the determination can be based on the required breakdown pressure and diagenetic rock typing results. The second workflow can be used to guide the actions or procedures to be taken after drilling. The workflow includes the calculation of in-situ stress changes due to drilling rock fragmentation using finite elements. Natural fractures' information along the final well trajectory are extracted. An evaluation can determine whether the natural fractures surrounding the wellbore can shear slip. This will indicate whether drilling can stimulate the rock. A check is made whether UBCTD well should be hydraulically fractured if no natural production happens with a good production rate.

In-situ stress changes due to drilling rock fragmentation can be simulated, leading to an evaluation of natural fracture stability (rarely considered in conventional oil and gas industry practices). Information about natural fractures (size, dip, and azimuth) can be extracted along the well trajectory from the 3D geomechanics model. The stimulated rock volume can be evaluated along the well trajectory. The workflows include steps related to logging data processing, borehole image analysis, calculation of mechanical properties, calculate in-situ stresses, simulate the stress changes due to drilling rock fragmentation and update the in-situ stresses after drilling, property modeling, natural fracture prediction, check whether natural fractures can shear slip or reactivate after drilling, calculation of required breakdown pressure, and optimize pump schedule through hydraulic fracturing modeling considering the interaction between hydraulic fractures and discrete natural fractures. Workflows described in the present disclosure were developed based on real case studies of UBCTD wells in deep and tight gas reservoirs, which generally need high breakdown pressure for clustered perforation hydraulic fracturing method if cased holes are used.

### Workflow/Criteria for Selecting Stimulation Method

This section describes the two workflows related to UBCTD. The first workflow is used to determine whether a well should be drilled with UBCTD. The second workflow is used to check whether the natural fractures along the final well trajectory can be reactivated or shear slip due to drilling rock fragmentation. The drilling rock removal will induce in-situ stress changes, which likely trigger fracture slips. This is done to check whether the well should be hydraulically fractured after drilling and before production. The workflows developed here are particularly useful for deep and tight gas reservoirs.

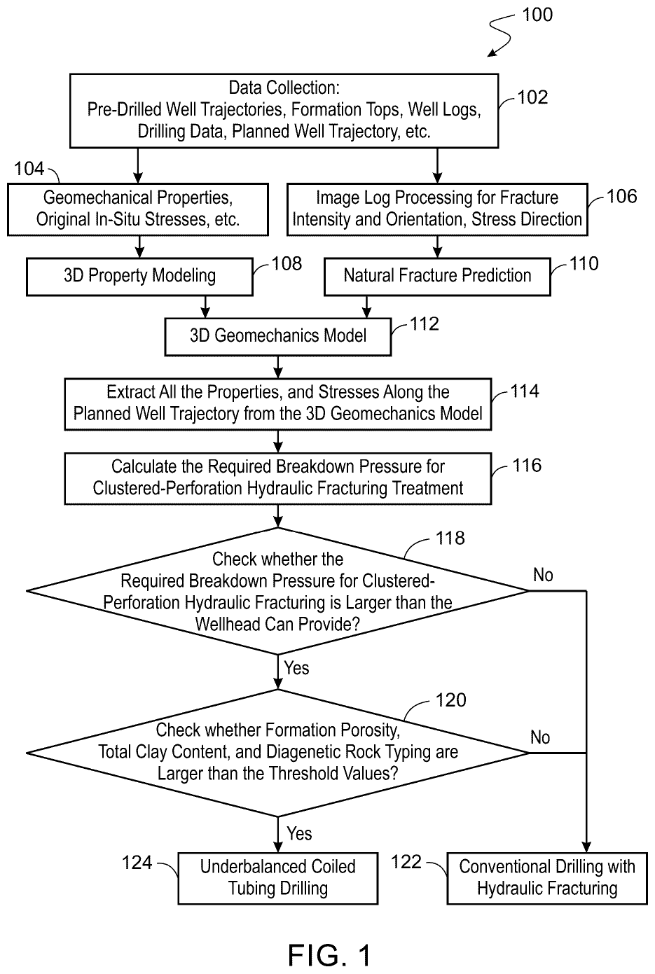

FIG. 1 is a flow diagram of an example of an integrated workflow 100 for determining whether a well should be drilled with conventional drilling or underbalanced coiled tubing drilling, according to some implementations of the present disclosure. For example, conventional drilling wells can be fractured after drilling is done. UBCTD is only applicable to good formation rock with good porosity, permeability, and diagenesis rock typing, but having a slow rate-of-penetration issue. Originally no hydraulic fracturing treatments are planned at the time of planning. UBCTD wells are drilled with smaller borehole diameters with the hope of fast rate of penetration and producing naturally as well. UBCTD can be fractured using special technology if necessary, which most likely generates longitudinal fractures.

As shown in FIG. 1, key components of the first workflow include the following: At 102, data collection occurs, in which data is collected for planned well trajectories, formation tops, and well logs for previously drilled and operated wells. At 104, geomechanical properties are estimated, including original in-situ stresses. At 106, image log processing occurs for fracture intensity and maximum horizontal stress orientation. At 108, three-dimensional (3D) property modeling is completed. At 110, natural fracture predictions (NFP) are made. At 112, a 3D geomechanics model is established, in which NFP can be contained in the 3D geomechanics model for hydraulic fracturing modeling and fracture stability analysis. At 114, properties are extracted, and stresses along the planned well trajectory are determined from the 3D geomechanics model. At 116, the required breakdown pressure for clustered-perforation hydraulic fracturing treatment is calculated. At 118, a check is made whether the required breakdown pressure for the cluster-perforation hydraulic fracturing is larger than the wellhead can provide. If not, then the cluster-perforation hydraulic fracturing is relatively easy to achieve. In this case, at 122, conventional drilling with hydraulic fracturing, and the well can be drilled with a cased hole. The well can be hydraulically fractured later. If, at 118, the required breakdown pressure is higher than the wellhead can provide, then a check is made at 120 whether the rock quality is good, e.g., the formation, porosity, total clay content, and diagenetic rock typing are larger than threshold values, then UBCTD can occur at 124.

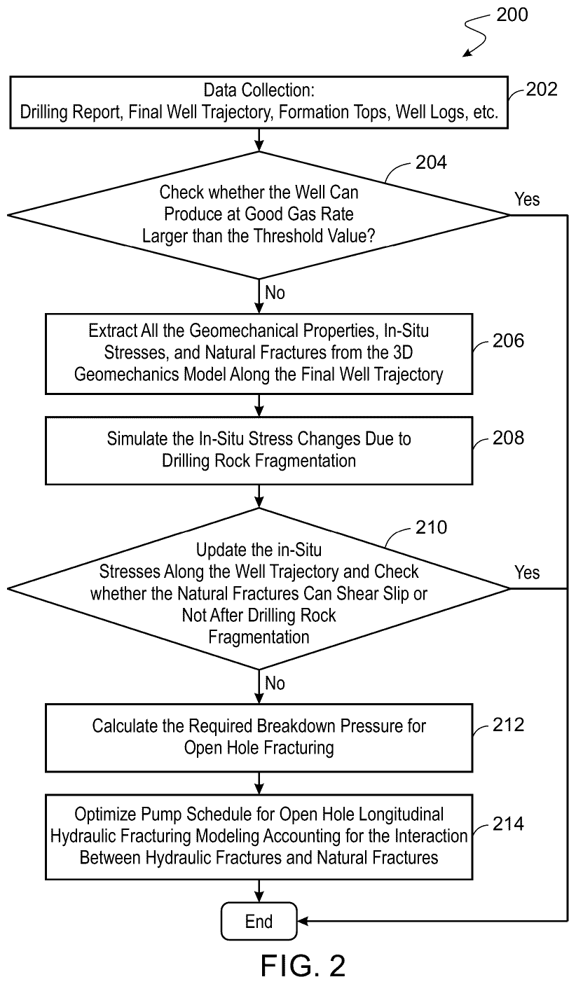

FIG. 2 is a flow diagram of an example of an integrated workflow 200 for actions and procedures to be followed after a UBCTD well is drilled, according to some implementations of the present disclosure. The workflow 200 is an integrated geomechanics workflow for evaluating UBCTD wells. At 202, data collection occurs, in which data is collected from drilling reports, a final well trajectory, formation tops, and well logs for the well. At 204, a check is whether the well can produce naturally at a good gas rate, e.g., the well does not need further stimulation before production. If not, then at 206, all the geomechanical properties are extracted, as are in-situ stresses and natural fractures along the final well trajectory. At 208, in-situ stress changes due to drilling rock fragmentation are simulated. At 210, in-situ stresses along the well trajectory are updated, and a check is made whether the stress changes can trigger the natural fractures to shear slip and stimulate the rock volume. If so, no further stimulation is required. Otherwise, at 212, the required breakdown pressure is calculated with the updated in-situ stresses. At 214, the pump schedule is optimized through hydraulic fracturing modeling, which can account for the interactions between hydraulic fractures and natural fractures.

For deep and tight gas reservoirs with high breakdown pressure, cased hole/perforation hydraulic fracturing treatment can be difficult to complete. In this situation, the workflow 100 can be used to check whether UBCTD can be a good choice. The present disclosure describes procedures for determining whether a well should be drilled with UBCTD for natural production, and whether further stimulation is needed for UBCTD wells before production.

### Features of the Integrated Workflows

### Formation Image Log Processing and Natural Fracture Prediction

For naturally fractured reservoirs, hydraulic fracturing modeling can account for the interaction between hydraulic fractures and natural fractures. Such modeling can include a discrete fracture network (DFN) model embedded in the 3D geomechanics model for fracture stability analysis and hydraulic fracturing modeling.

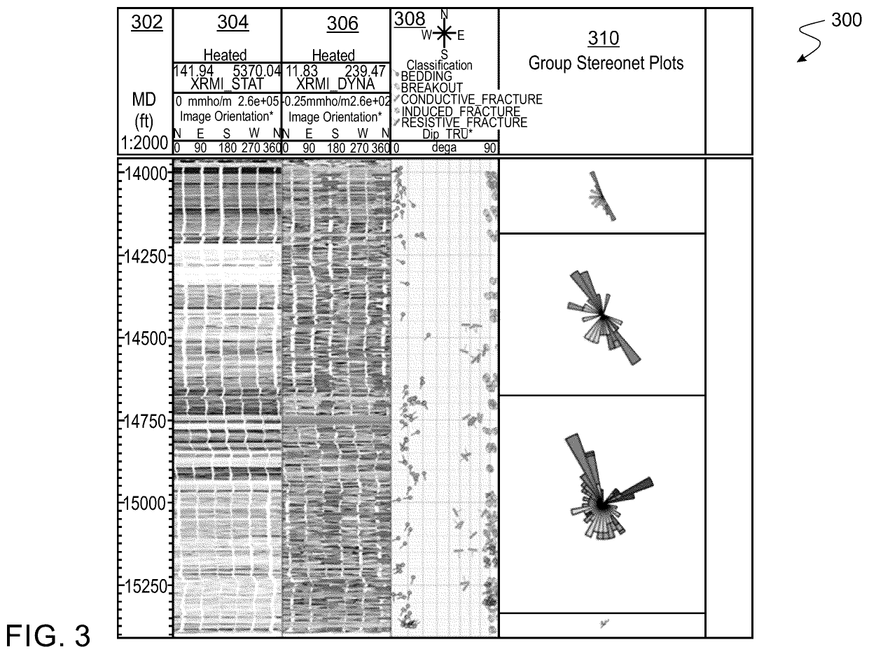

FIG. 3 is a diagram showing a log-plot 300 including formation image log processing and interpretation, according to some implementations of the present disclosure. The log-plot 300 can be used to predict natural fracture networks in field and well scale. The log-plot 300 includes fracture orientations, dip angles, dip azimuths, and fracture types. The log-plot 300 includes a depth scale 302, logs 304 and 306, fracture orientations 308, and group stereonet plots 310. Track 1 is the measured depth. Tracks 2-3 are the borehole image logs. Track 4 shows the different kinds of fractures or breakouts from drilling. Track 5 shows the azimuths of different breakouts, which can identify the maximum horizontal stress direction.

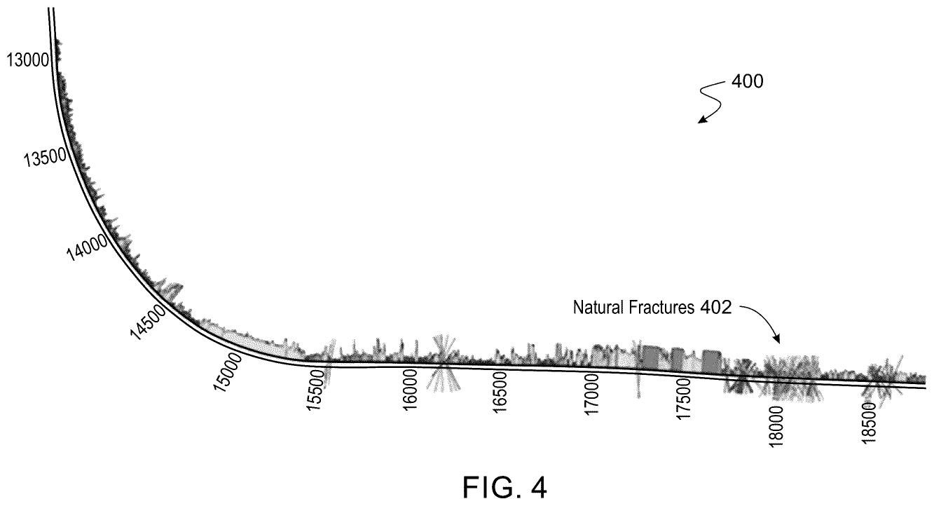

FIG. 4 is a diagram showing an example plot 400 including natural fractures 402 along the well trajectory, according to some implementations of the present disclosure. The natural fractures are shown with dip and azimuth identified from the image log. The fracture data can be used as input to predict natural fracture distributions in 3D space.

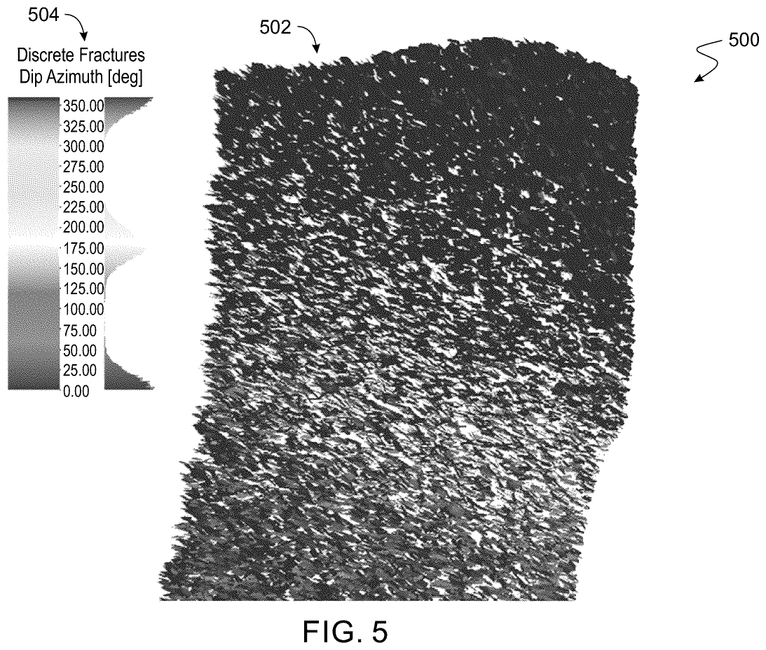

FIG. 5 is a diagram showing an example model of a predicted discrete fracture network 500, according to some implementations of the present disclosure. The predicted discrete fracture network 500 contains various fracture sizes and orientations (azimuths, dips) for fractures in a plot 502, with intensities identified by an intensities scale 504.

### Rock Quality and Rock Diagenetic Typing

The diagenetic rock typing is one of the components of this workflow, which will be used to evaluate reservoir rock quality. This part is to generate different diagenetic rock types according to effective porosity, and total clay content variation. Compaction and cementation are the two main diagenetic processes that reduce sandstone intergranular porosity. Compaction usually is the function of burial depth, and heavy compaction is expected with the increased burial depth. Cementation is more important compared to compaction for the same sandstone reservoir since the heterogeneity was mainly caused by different types and amounts of the cements. For example, quartz cemented clean sandstone has much better porosity and permeability than clay rich sandstones, especially permeability in case of similar porosity. Therefore, the clay content including illite, kaolinite, and chlorite is critical for different diagenetic rock types. That is why this invented workflow uses the total clay as one of the key factors to evaluating sandstone diagenetic rock typing.

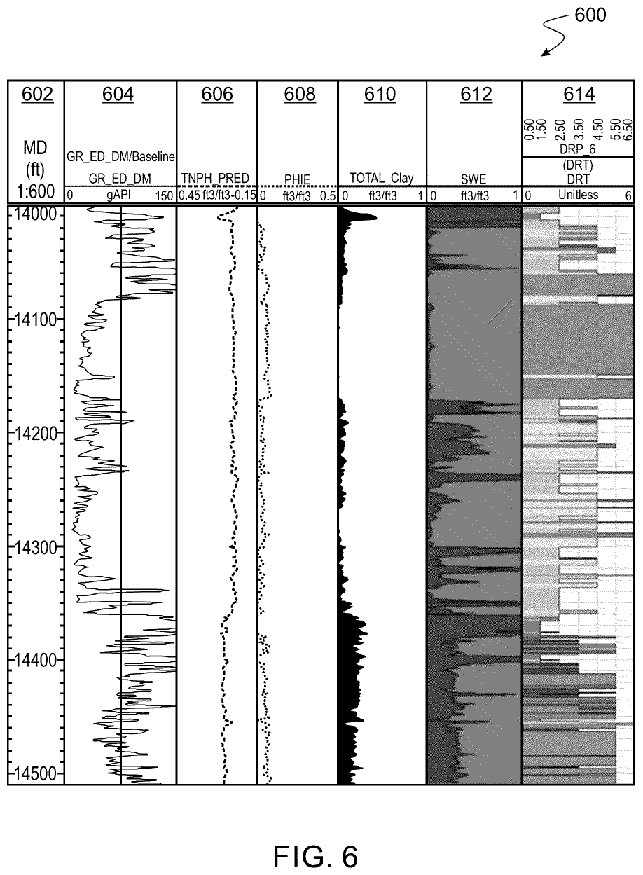

Diagenetic rock typing criteria can be based on sandstone petrography studies. For example, studies can conclude that the total clay content is less than 5% in clean sandstones. As a result, wells drilled by UBCTD can naturally produce gas without fracturing. Sandstone frackability analysis results indicate, for example, that sandstone having more than 3% porosity and less than 10% total clay can contribute to production after hydraulic fracking. Accounting for the above-mentioned factors, tight sandstone can be divided into six different types of diagenetic rock types (DRT), namely TYPE1, TYPE2, TYPE3, TYPE4, TYPE5, and TYPE6 (see FIG. 6). In higher rock type numbers, the rock quality will be better for production, which represent the areas that fractures should propagate into.

FIG. 6 is a diagram showing an example of a depth chart 600 including rock porosity, total clay content, water content, and rock quality typing. Components of the depth chart 600 are plotted relative to a mud depth (MD) 602 (e.g., in feet), including a GR_ED_DM baseline 604, a TNPH prediction 606 (e.g., in cubic feet (ft³) per cubic feet), an effectively porosity (PHIE) (e.g., in ft³/ft³), a total clay 608, an effective water saturation (SWE) 612 (e.g., in ft³/ft³), and a DRT 614 (unitless). The chart can be used to easily see the areas in which DRT=6 and where the rock has a low clay content and a higher porosity, which is good for production. This represents the ideal location for perforating. For the lower DRT areas less than 3, the rock quality is poor and not good for production.

### Predict In-Situ Stress Changes Due to Drilling Rock Fragmentation

In petroleum geomechanics, estimating the in-situ stresses is very important to predict mud weight window for drilling and required breakdown pressure for hydraulic fracturing, etc. The in-situ stress changes around wellbore due to drilling rock fragmentation were rarely calculated in the oil and gas industry. Generally, the far-field in-situ stresses are assumed to be the same as those before drilling, which are also used for hydraulic fracturing modeling. The present disclosure simulates the wellbore stress changes induced by drilling rock fragmentation. This is very critical to evaluate whether discrete natural fractures surrounding the wellbore can shear slip or reactivate. In the present disclosure, a numerical method will be used to simulate the in-situ stress changes since no analytical models exist for this purpose.

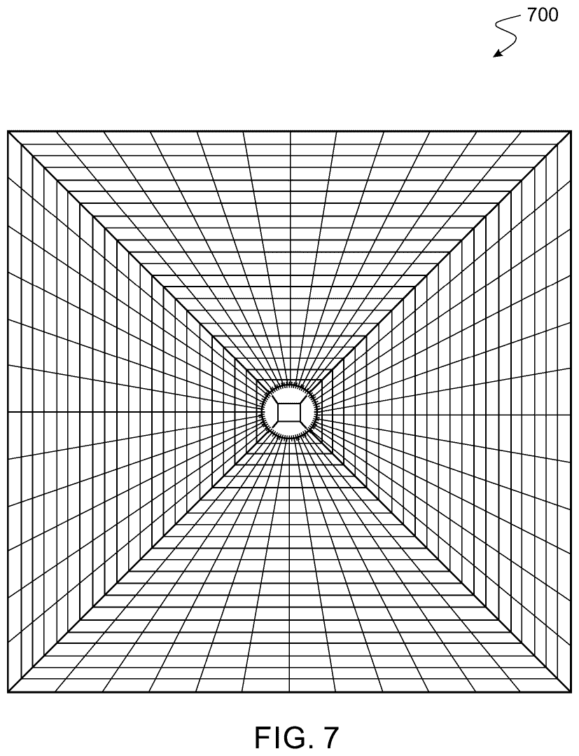

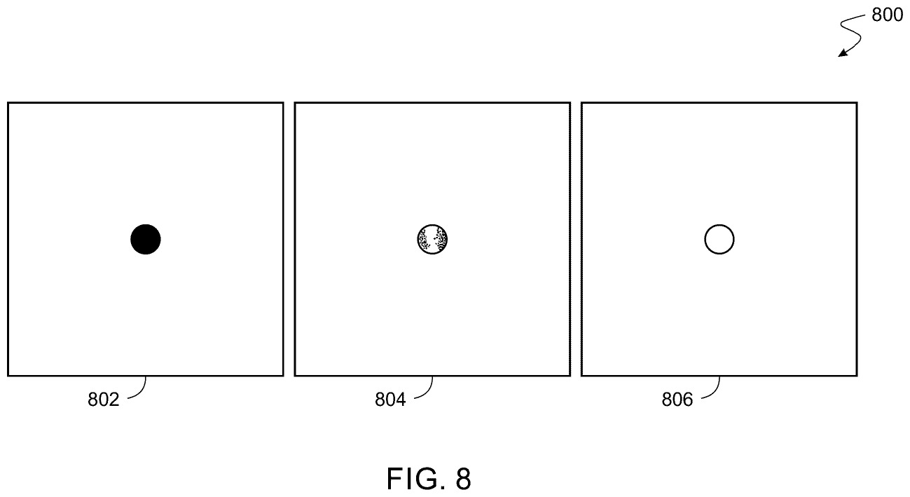

FIG. 7 shows an example of a finite element model 700 for simulating the wellbore stress changes due to drilling rock fragmentation, according to some implementations of the present disclosure. Three steps that are used in the finite element model 700 are described with reference to FIG. 8.

FIG. 8 is a diagram showing an example of a modeling stage diagram 800 for predicting stress changes due to drilling rock fragmentation, according to some implementations of the present disclosure. A first step 802 is used to simulate the in-situ stresses. A second step 804 is used to simulate drilling rock fragmentation, but with rock still in the borehole, in which the rock is considered as being without cohesion (granular material) but with frictional angle. A third step 806 is used to simulate the rock being removed from the borehole, which is a very critical procedure to simulate the in-situ stress changes after drilling. In conventional systems in the oil and gas industry, this effect is rarely considered.

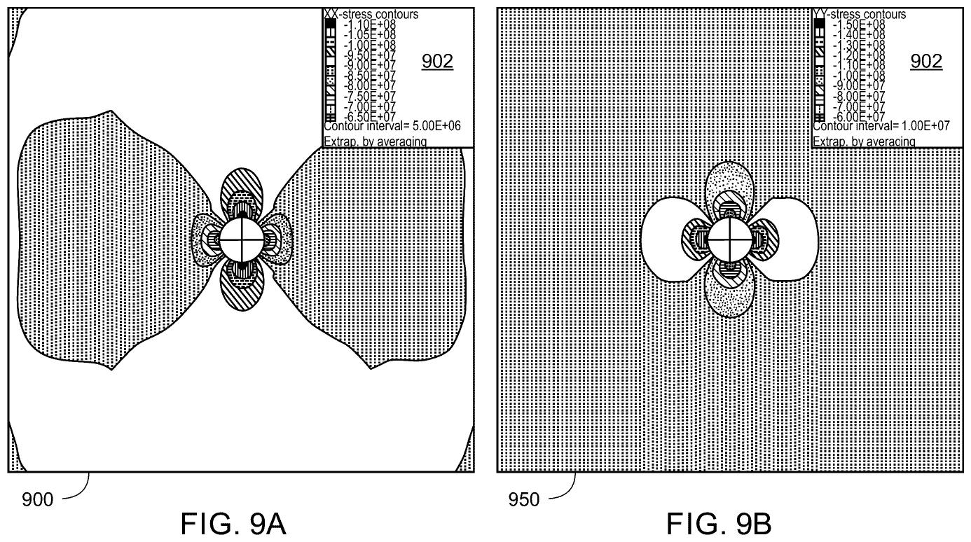

FIGS. 9A and 9B are diagrams 900, 950 showing examples of in-situ stresses in horizontal and vertical directions, respectively, after drilling rock fragmentation, according to some implementations of the present disclosure. For example, the diagrams 900, 950 show the final in-situ stresses around the borehole after rock being completely removed, which will be used to evaluate the natural fracture stability. Stresses in the diagrams 900, 950 are depicted by shading according to a stress intensity key 902.

### Evaluation of Natural Fracture Stability Due to Drilling Rock Fragmentation

Natural fractures need stresses and pore pressure changes to trigger shearing slip, which can be activated if the shear stresses acting on the fracture surfaces overcome the resistance to slip of the adjacent rock blocks. Pore pressure change that is due to fluid injection can be the main reason. The shear resistance is due to friction, which is proportional to effective normal stress (e.g., the difference between the normal stress acting on the fault, and the fluid pressure) in the fault. The fault remains in a stable state as long as the magnitude of shear stress is lower than the shear resistance or frictional strength.

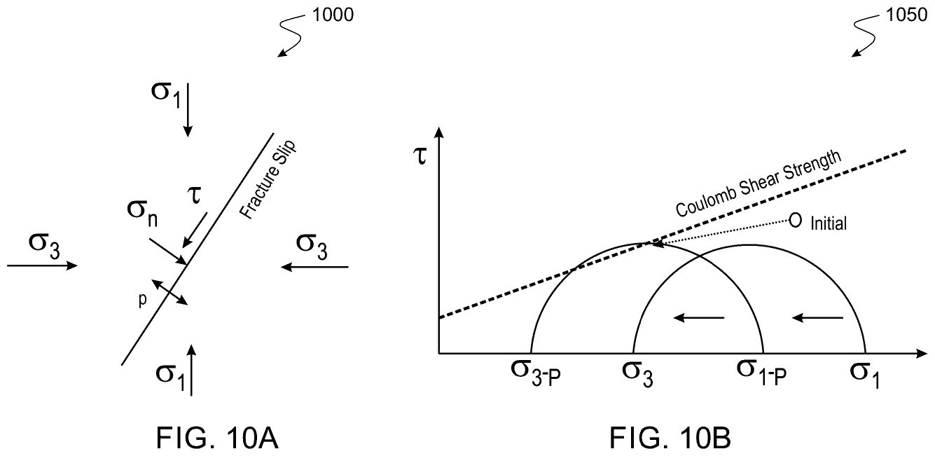

FIGS. 10A and 10B illustrate examples 1000 and 1050 showing effects of Coulomb stress change and shear strength, according to some implementations of the present disclosure. For example, FIGS. 10A and 10B show the in-situ stress state around fractures and the impact of pore pressure change on trigger fracture shearing slip. The critical condition is called the Coulomb strength criterion, which reflects two fundamental concepts, friction and effective stress by:

τ=μ(σₙ−p) (1)

Where τ is . . . μ is the frictional coefficient of fracture surface, σₙ is the normal compression stress, and p is pressure.

The presence of effective stress in the Coulomb criterion shows that the fluid pressure p counterbalances the effect of the normal compression stress σₙ. The Coulomb criterion indicates that fault slip can be triggered by either decrease of the normal stress or an increase of the pore pressure, or an increase of the shear stress. Based on this, Coulomb stress change (ΔCSC) can be used to evaluate a natural fracture becoming stable or unstable due to change of pore pressure and stress, which is given by:

ΔCSC=Δτ−μ(Δσₙ−Δp) (2)

where Δτ is the shear stress change on a fracture in the fracture direction (positive in the direction of fracture slip), Δσₙ represents the compressive stress change that clamps or unclamps the fracture (positive if the fracture is in compression), Δp is the pore pressure change in the fracture that unclamps the fracture, and μ is the frictional coefficient of the fracture surface. Based on the definition of ΔCSC, a positive change of ΔCSC promotes shearing slip and a negative change inhibits fracture shearing slip. Also, the natural fracture stability can be evaluated using the following equation:

FVAL=τ−[c+tan ∅(σₙ−p)] (3)

where FVAL represents the fracture shear failure value, τ is shear stress, c is cohesion, and tan ∅(σₙ−p) represents the resistance.

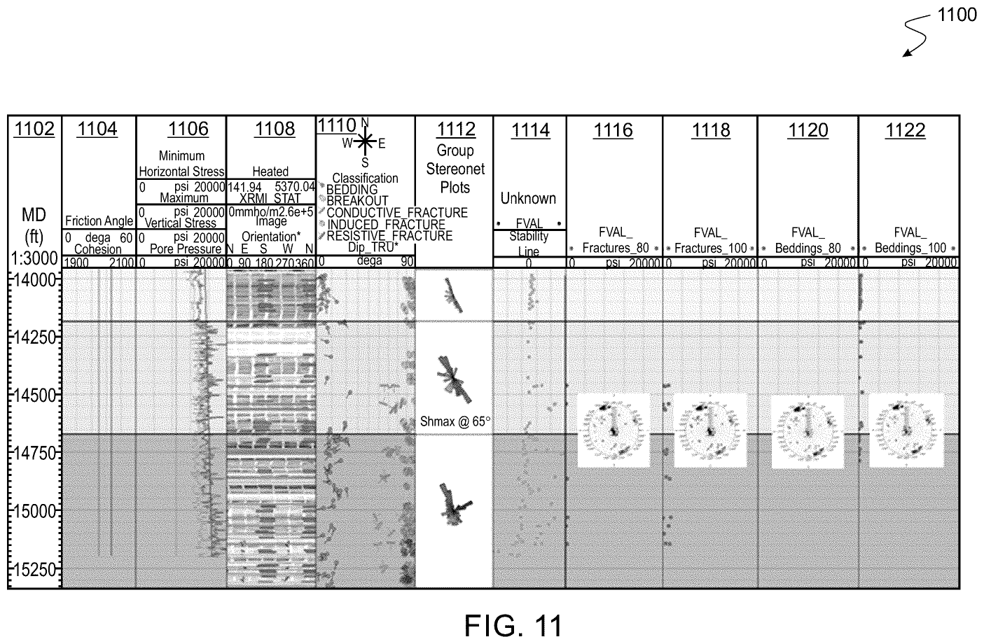

FIG. 11 is a diagram showing an example of a depth chart 1100 illustrating a natural fracture stability analysis, according to some implementations of the present disclosure. The natural fracture stability is due to stress changes induced by drilling rock fragmentation. FIG. 11 shows some nature fractures will shear slip due to stress changes related to drilling rock fragmentation. This is good for improving the permeability and boosting production rate after underbalanced coiled tubing drilling.

Components of the depth chart 1100 are plotted relative to a mud depth (MD) 1102 (e.g., in feet), including a friction angle 1104, stresses and pore pressure graph 1106, an image orientation 1108, fracture types 1110, group stereonet plots 1112, a stability plot 1114, and FVAL fractures 1116 and 1118, and FVAL beddings 1120 and 1122. From plot 1114-1118, it can be seen where the fractures and beddings will shear slip due to drilling rock removal and their corresponding azimuths and dips. This can indicate whether the fractures and beddings that the well trajectory penetrated can be reactivated or not.

### Stimulating UBCTD Wells

After evaluating the natural fracture stability, a decision can be made whether the UBCTD well needs further stimulation or not. UBCTD wells are open holes. If not many natural fractures have not been reactivated due to drilling rock fragmentation, a final stimulation can be applied to generate longitudinal fractures through fluid injection. The required breakdown pressure can be calculated, and the pump schedule can be optimized through hydraulic fracturing modeling accounting for the interaction between hydraulic fractures and discrete natural fractures.

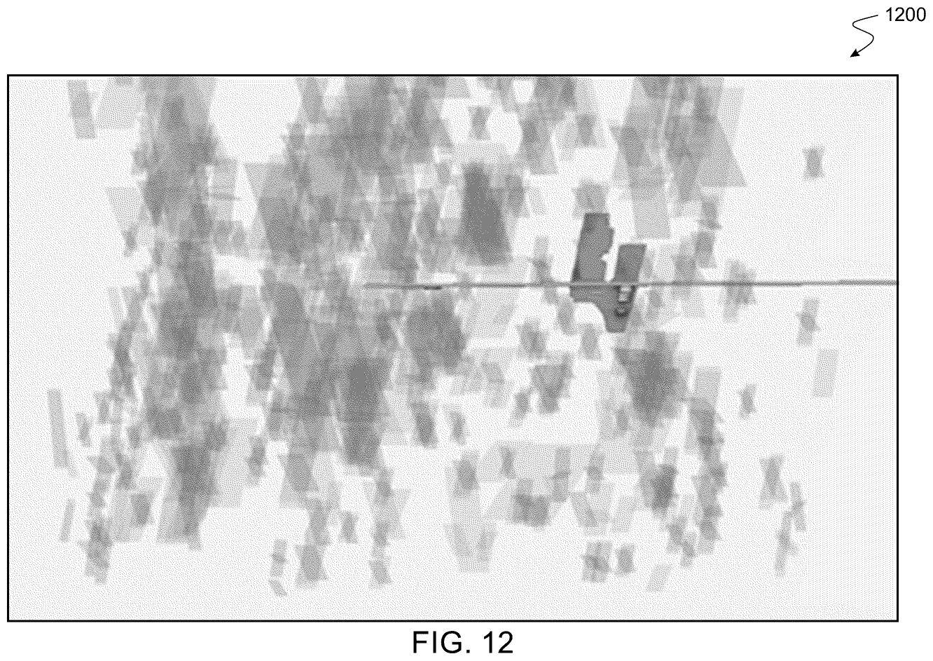

FIG. 12 is a diagram of an example of a plot 1200 showing hydraulic fractures propagating in a naturally fractured reservoir, according to some implementations of the present disclosure. The plot 1200 models hydraulic fractures propagating in a formation with a lot of natural fractures, with different sizes, azimuths, and dip angles. Accounting for the types of interactions can lead, for example, to a more objective and accurate optimization of a hydraulic fracturing injection pump schedule.

Deep and tight gas reservoirs can rely heavily on hydraulic fracturing stimulation for good production. However, cased hole/perforated hydraulic fracturing completion methods are not the only choice. For reservoirs with relatively good porosity, permeability, mobility, and numerous natural fractures (observed from image log), UBCTD may be a good choice for a fast rate of penetration. Determining such a choice can be based on evaluation, such as through rock diagenetic typing and geomechanics analysis. The workflow 100 can be used for determining whether a well should be drilled with underbalanced coiled tubing drilling. The drilling rock fragmentation process is likely to trigger the natural fractures surrounding the wellbore to shear slip. This can represent a way to stimulate the rock. If this cannot reach the goal of good production, fluid can be further injected to stimulate the well, and most likely a longitudinal fracture will result. The present disclosure presents the corresponding workflows, which can be used for determining whether UBCTD should be used for a well and the corresponding actions left for stimulating UBCTD wells in deep and tight gas reservoirs. Following the disclosed workflows and procedures, field engineers can avoid uncertainties, which not only can save a lot of time and money, but also provide a better chance to stimulate the wells with good production rates.

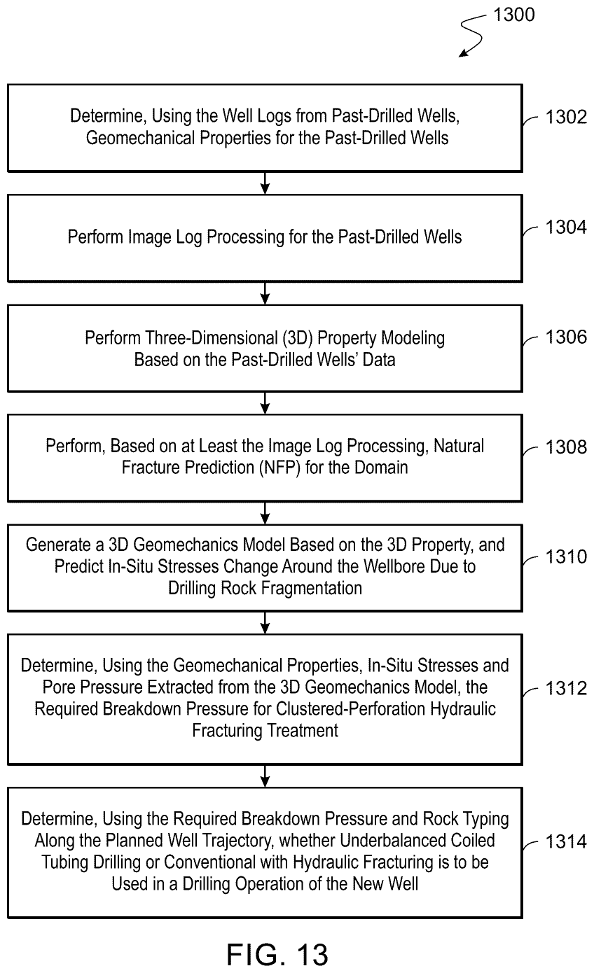

FIG. 13 is a flowchart of an example of a method 1300 for determining whether underbalanced coiled tubing drilling or conventional drilling with hydraulic fracturing is to be used in a drilling operation of a new well. For clarity of presentation, the description that follows generally describes method 1300 in the context of the other figures in this description. However, it will be understood that method 1300 can be performed, for example, by any suitable system, environment, software, and hardware, or a combination of systems, environments, software, and hardware, as appropriate. In some implementations, various steps of method 1300 can be run in parallel, in combination, in loops, or in any order.

At 1302, estimates of geomechanical properties for past-drilled wells are determined using past-drilled wells' logs. For example, the estimates of geomechanical properties for the past-drilled wells can include estimates for Young's modulus, Poisson ratio, Biot coefficient, unconfined compressive strength, and tensile strength, etc. From 1302, method 1300 proceeds to 1304.

At 1304 (see FIG. 3), image log processing is performed for the past-drilled wells in the field. The image log processing can include fracture intensity and determining maximum horizontal stress orientation, for example. From 1304, method 1300 proceeds to 1306.

At 1306, three-dimensional (3D) property modeling of the field is performed using the estimates of geomechanical properties for the past-drilled wells. The 3D property modeling can include, for example, Young's modulus, Poisson ratio, Biot coefficient, unconfined compressive strength, and tensile strength. The property modeling can include the process of filling cells of the 3D grid with discrete or continuous properties. The 3D property model can be used to generate the 3D geomechanics model and to simulate the in-situ stress changes due to drilling rock fragmentation. From 1306, method 1300 proceeds to 1308.

At 1308 (see FIGS. 2-5), natural fracture prediction (NFP) for the field is performed based at least on image log processing. Based on the image log processing results, fracture data along the well trajectory can be obtained, which includes fracture locations, fracture types, dip angles, dip azimuths, and the like. The fracture data can be provided to a fracture simulator and can be upscaled into 3D grid. A fracture driver in the entire 3D grid can be used to provide additional information about the lateral/spatial extent of fractures. Four types of fracture drivers can be used for fracture modeling, which are geologically related information (porosity, facies, etc.), seismic (acoustic impedance), geomechanical aspect (fault related), and stress-related. Then, a fracture network model can be created using either deterministic approaches or stochastic approaches. The NFP prediction can give the distribution of discrete fractures in terms of size, azimuth, and dip. From 1308, method 1300 proceeds to 1310.

At 1310, a 3D geomechanics model for field is generated using the 3D property model and the NFP model covering the past-drilled wells. The discrete fracture network is contained in the 3D geomechanics model for hydraulic fracturing modeling and fracture stability analysis. As an example, the 3D geomechanics model can include in-situ stresses, pore pressure, and geomechanical properties. The 3D geomechanics model can be further used to simulate the in-situ stress change due to drilling rock fragmentation. From 1310, method 1300 proceeds to 1312.

At 1312, a required breakdown pressure for a clustered-perforation hydraulic fracturing treatment for a new well trajectory is determined using the extracted geomechanical properties, in-situ stress, and pore pressure along the planned well trajectory from the built 3D geomechanics model at 1310. From 1312, method 1300 proceeds to 1314.

At 1314, a determination is made whether underbalanced coiled tubing drilling or conventional drilling with hydraulic fracturing is to be used in a drilling operation of the new well. The determination is made using the required breakdown pressure for the clustered-perforation hydraulic fracturing treatment for the new well. After 1314, method 1300 can stop.

In some implementations, method 1300 further includes actions to be done after a well being drilled is determined to be unable to produce normally. This is especially important for UBCTD drilling in order to evaluate whether the fractures penetrated by the well trajectory will be stimulated or not due to UBCTD drilling. The further actions, described in more detail with reference to FIG. 2, include the following. Natural fracture information is extracted for natural fractures along a final well trajectory of the new well. Using the natural fracture information, changes in in-situ stresses that are attributed to drilling rock fragmentation are simulated along the final well trajectory of the new well. Based on the simulating, the in-situ stresses along the final well trajectory are updated. Finally, a determination is made, based on the updated in-situ stresses along the final well trajectory, whether the natural fractures can shear slip or not after drilling the new well.

In some implementations, method 1300 further includes diagenetic rock typing analysis for sweet spot identification and drilling rate of penetration for cost evaluation, which are very useful to make decision for selecting drilling program and well placement.

In some implementations, in addition to (or in combination with) any previously-described features, techniques of the present disclosure can include the following. Outputs of the techniques of the present disclosure can be performed before, during, or in combination with wellbore operations, such as to provide inputs to change the settings or parameters of equipment used for drilling. Examples of wellbore operations include forming/drilling a wellbore, hydraulic fracturing, and producing through the wellbore, to name a few. The wellbore operations can be triggered or controlled, for example, by outputs of the methods of the present disclosure. In some implementations, customized user interfaces can present intermediate or final results of the above described processes to a user. Information can be presented in one or more textual, tabular, or graphical formats, such as through a dashboard. The information can be presented at one or more on-site locations (such as at an oil well or other facility), on the Internet (such as on a webpage), on a mobile application (or “app”), or at a central processing facility. The presented information can include suggestions, such as suggested changes in parameters or processing inputs, that the user can select to implement improvements in a production environment, such as in the exploration, production, and/or testing of petrochemical processes or facilities. For example, the suggestions can include parameters that, when selected by the user, can cause a change to, or an improvement in, drilling parameters (including drill bit speed and direction) or overall production of a gas or oil well. The suggestions, when implemented by the user, can improve the speed and accuracy of calculations, streamline processes, improve models, and solve problems related to efficiency, performance, safety, reliability, costs, downtime, and the need for human interaction. In some implementations, the suggestions can be implemented in real-time, such as to provide an immediate or near-immediate change in operations or in a model. The term real-time can correspond, for example, to events that occur within a specified period of time, such as within one minute or within one second. Events can include readings or measurements captured by downhole equipment such as sensors, pumps, bottom hole assemblies, or other equipment. The readings or measurements can be analyzed at the surface, such as by using applications that can include modeling applications and machine learning. The analysis can be used to generate changes to settings of downhole equipment, such as drilling equipment. In some implementations, values of parameters or other variables that are determined can be used automatically (such as through using rules) to implement changes in oil or gas well exploration, production/drilling, or testing. For example, outputs of the present disclosure can be used as inputs to other equipment and/or systems at a facility. This can be especially useful for systems or various pieces of equipment that are located several meters or several miles apart, or are located in different countries or other jurisdictions.

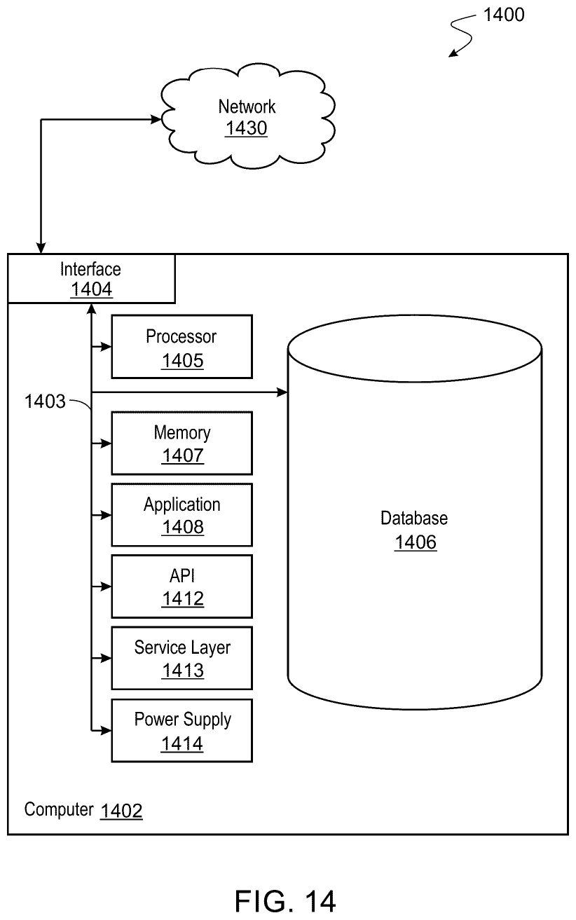

FIG. 14 is a block diagram of an example computer system 1400 used to provide computational functionalities associated with described algorithms, methods, functions, processes, flows, and procedures described in the present disclosure, according to some implementations of the present disclosure. The illustrated computer 1402 is intended to encompass any computing device such as a server, a desktop computer, a laptop/notebook computer, a wireless data port, a smart phone, a personal data assistant (PDA), a tablet computing device, or one or more processors within these devices, including physical instances, virtual instances, or both. The computer 1402 can include input devices such as keypads, keyboards, and touch screens that can accept user information. Also, the computer 1402 can include output devices that can convey information associated with the operation of the computer 1402. The information can include digital data, visual data, audio information, or a combination of information. The information can be presented in a graphical user interface (UI) (or GUI).

The computer 1402 can serve in a role as a client, a network component, a server, a database, a persistency, or components of a computer system for performing the subject matter described in the present disclosure. The illustrated computer 1402 is communicably coupled with a network 1430. In some implementations, one or more components of the computer 1402 can be configured to operate within different environments, including cloud-computing-based environments, local environments, global environments, and combinations of environments.

At a top level, the computer 1402 is an electronic computing device operable to receive, transmit, process, store, and manage data and information associated with the described subject matter. According to some implementations, the computer 1402 can also include, or be communicably coupled with, an application server, an email server, a web server, a caching server, a streaming data server, or a combination of servers.

The computer 1402 can receive requests over network 1430 from a client application (for example, executing on another computer 1402). The computer 1402 can respond to the received requests by processing the received requests using software applications. Requests can also be sent to the computer 1402 from internal users (for example, from a command console), external (or third) parties, automated applications, entities, individuals, systems, and computers.

Each of the components of the computer 1402 can communicate using a system bus 1403. In some implementations, any or all of the components of the computer 1402, including hardware or software components, can interface with each other or the interface 1404 (or a combination of both) over the system bus 1403. Interfaces can use an application programming interface (API) 1412, a service layer 1413, or a combination of the API 1412 and service layer 1413. The API 1412 can include specifications for routines, data structures, and object classes. The API 1412 can be either computer-language independent or dependent. The API 1412 can refer to a complete interface, a single function, or a set of APIs.

The service layer 1413 can provide software services to the computer 1402 and other components (whether illustrated or not) that are communicably coupled to the computer 1402. The functionality of the computer 1402 can be accessible for all service consumers using this service layer. Software services, such as those provided by the service layer 1413, can provide reusable, defined functionalities through a defined interface. For example, the interface can be software written in JAVA, C++, or a language providing data in extensible markup language (XML) format. While illustrated as an integrated component of the computer 1402, in alternative implementations, the API 1412 or the service layer 1413 can be stand-alone components in relation to other components of the computer 1402 and other components communicably coupled to the computer 1402. Moreover, any or all parts of the API 1412 or the service layer 1413 can be implemented as child or sub-modules of another software module, enterprise application, or hardware module without departing from the scope of the present disclosure.

The computer 1402 includes an interface 1404. Although illustrated as a single interface 1404 in FIG. 14, two or more interfaces 1404 can be used according to particular needs, desires, or particular implementations of the computer 1402 and the described functionality. The interface 1404 can be used by the computer 1402 for communicating with other systems that are connected to the network 1430 (whether illustrated or not) in a distributed environment. Generally, the interface 1404 can include, or be implemented using, logic encoded in software or hardware (or a combination of software and hardware) operable to communicate with the network 1430. More specifically, the interface 1404 can include software supporting one or more communication protocols associated with communications. As such, the network 1430 or the interface's hardware can be operable to communicate physical signals within and outside of the illustrated computer 1402.

The computer 1402 includes a processor 1405. Although illustrated as a single processor 1405 in FIG. 14, two or more processors 1405 can be used according to particular needs, desires, or particular implementations of the computer 1402 and the described functionality. Generally, the processor 1405 can execute instructions and can manipulate data to perform the operations of the computer 1402, including operations using algorithms, methods, functions, processes, flows, and procedures as described in the present disclosure.

The computer 1402 also includes a database 1406 that can hold data for the computer 1402 and other components connected to the network 1430 (whether illustrated or not). For example, database 1406 can be an in-memory, conventional, or a database storing data consistent with the present disclosure. In some implementations, database 1406 can be a combination of two or more different database types (for example, hybrid in-memory and conventional databases) according to particular needs, desires, or particular implementations of the computer 1402 and the described functionality. Although illustrated as a single database 1406 in FIG. 14, two or more databases (of the same, different, or combination of types) can be used according to particular needs, desires, or particular implementations of the computer 1402 and the described functionality. While database 1406 is illustrated as an internal component of the computer 1402, in alternative implementations, database 1406 can be external to the computer 1402.

The computer 1402 also includes a memory 1407 that can hold data for the computer 1402 or a combination of components connected to the network 1430 (whether illustrated or not). Memory 1407 can store any data consistent with the present disclosure. In some implementations, memory 1407 can be a combination of two or more different types of memory (for example, a combination of semiconductor and magnetic storage) according to particular needs, desires, or particular implementations of the computer 1402 and the described functionality. Although illustrated as a single memory 1407 in FIG. 14, two or more memories 1407 (of the same, different, or combination of types) can be used according to particular needs, desires, or particular implementations of the computer 1402 and the described functionality. While memory 1407 is illustrated as an internal component of the computer 1402, in alternative implementations, memory 1407 can be external to the computer 1402.

The application 1408 can be an algorithmic software engine providing functionality according to particular needs, desires, or particular implementations of the computer 1402 and the described functionality. For example, application 1408 can serve as one or more components, modules, or applications. Further, although illustrated as a single application 1408, the application 1408 can be implemented as multiple applications 1408 on the computer 1402. In addition, although illustrated as internal to the computer 1402, in alternative implementations, the application 1408 can be external to the computer 1402.

The computer 1402 can also include a power supply 1414. The power supply 1414 can include a rechargeable or non-rechargeable battery that can be configured to be either user- or non-user-replaceable. In some implementations, the power supply 1414 can include power-conversion and management circuits, including recharging, standby, and power management functionalities. In some implementations, the power supply 1414 can include a power plug to allow the computer 1402 to be plugged into a wall socket or a power source to, for example, power the computer 1402 or recharge a rechargeable battery.

There can be any number of computers 1402 associated with, or external to, a computer system containing computer 1402, with each computer 1402 communicating over network 1430. Further, the terms “client,” “user,” and other appropriate terminology can be used interchangeably, as appropriate, without departing from the scope of the present disclosure. Moreover, the present disclosure contemplates that many users can use one computer 1402 and one user can use multiple computers 1402.

Described implementations of the subject matter can include one or more features, alone or in combination.

For example, in a first implementation, a computer-implemented method includes the following. Estimates of geomechanical properties for past-drilled wells are determined using planned well trajectories, formation tops, and well logs from the past-drilled wells. Image log processing is performed for the past-drilled wells using the planned well trajectories, the formation tops, and the well logs for the past-drilled wells. Three-dimensional (3D) property modeling of the past-drilled wells is performed using the estimates of geomechanical properties for the past-drilled wells. Natural fracture prediction (NFP) for the past-drilled wells is performed based at least on the image log processing. A 3D geomechanics model is generated using the 3D property modeling of the past-drilled wells and the NFP. The NFP is contained in the 3D geomechanics model for hydraulic fracturing modeling and fracture stability analysis. A required breakdown pressure for a clustered-perforation hydraulic fracturing treatment for a new well is determined using the 3D geomechanics model. A determination is made whether underbalanced coiled tubing drilling or conventional drilling with hydraulic fracturing is to be used in a drilling operation of the new well. The determination is made based on the diagenetic rock typing and the required breakdown pressure for the clustered-perforation hydraulic fracturing treatment for the new well.

The foregoing and other described implementations can each, optionally, include one or more of the following features:

A first feature, combinable with any of the following features, where the estimates of geomechanical properties for the past-drilled wells include Young's modulus, Poisson ratio, Biot coefficient, unconfined compressive strength, and tensile strength.

A second feature, combinable with any of the previous or following features, where performing the image log processing for the past-drilled wells includes determining fracture intensity and maximum horizontal stress orientation.

A third feature, combinable with any of the previous or following features, where performing the 3D property modeling results in a 3D distribution of Young's modulus, Poisson ratio, Biot coefficient, unconfined compressive strength, and tensile strength, and wherein property modeling includes a process of filling cells of a 3D grid with one or both of discrete and continuous properties.

A fourth feature, combinable with any of the previous or following features, where performing the NFP for a field having past-drilled wells includes a discrete fracture network and results in a distribution of discrete natural fractures in terms of sizes and orientations, including azimuth and dip).

A fifth feature, combinable with any of the previous or following features, where generating the 3D geomechanics model includes predicting a 3D distribution of in-situ stresses, pore pressure, and geomechanical properties, and wherein the 3D geomechanics model is configured to simulate in-situ stress changes due to drilling rock fragmentation.

A sixth feature, combinable with any of the previous or following features, where the method further includes performing diagenetic rock typing analysis for sweet spot identification and drilling rate of penetration for cost evaluation, and making decision for selecting drilling program and well placement based on the diagenetic rock typing analysis.

A seventh feature, combinable with any of the previous or following features, where the method further includes: extracting natural fracture information along a final well trajectory of the new well; simulating, using the 3D property modeling and natural fracture information, changes in in-situ stresses along the final well trajectory of the new well that are induced by drilling rock fragmentation; updating, based on the simulating, the in-situ stresses along the final well trajectory; and determining, based at least on the updated in-situ stresses along the final well trajectory, whether the natural fractures can shear slip or not after drilling the new well.

In a second implementation, a non-transitory, computer-readable medium stores one or more instructions executable by a computer system to perform operations including the following. Estimates of geomechanical properties for past-drilled wells are determined using planned well trajectories, formation tops, and well logs from the past-drilled wells. Image log processing is performed for the past-drilled wells using the planned well trajectories, the formation tops, and the well logs for the past-drilled wells. Three-dimensional (3D) property modeling of the past-drilled wells is performed using the estimates of geomechanical properties for the past-drilled wells. Natural fracture prediction (NFP) is performed based at least on the image log processing. A 3D geomechanics model is generated using the 3D property modeling of the past-drilled wells and the NFP. The NFP is contained in the 3D geomechanics model for hydraulic fracturing modeling and fracture stability analysis. Required breakdown pressures for a clustered-perforation hydraulic fracturing treatment for a new well are determined using the 3D geomechanics model. A determination is made whether underbalanced coiled tubing drilling or conventional drilling with hydraulic fracturing is to be used in a drilling operation of the new well. The determination is made using the diagenetic rock typing and the required breakdown pressure for the clustered-perforation hydraulic fracturing treatment for the new well.

The foregoing and other described implementations can each, optionally, include one or more of the following features:

A first feature, combinable with any of the following features, where the estimates of geomechanical properties for the past-drilled wells include Young's modulus, Poisson ratio, Biot coefficient, unconfined compressive strength, and tensile strength.

A second feature, combinable with any of the previous or following features, where performing the image log processing for the past-drilled wells includes determining fracture types, orientations, fracture intensity and maximum horizontal stress orientation.

A third feature, combinable with any of the previous or following features, where performing the 3D property modeling results in a 3D distribution of Young's modulus, Poisson ratio, Biot coefficient, unconfined compressive strength, and tensile strength, and wherein property modeling includes a process of filling cells of a 3D grid with one or both of discrete and continuous properties.

A fourth feature, combinable with any of the previous or following features, where performing the NFP for a field having past-drilled wells includes a discrete fracture network and results in a distribution of discrete natural fractures in terms of sizes and orientations, including azimuth and dip).

A fifth feature, combinable with any of the previous or following features, where generating the 3D geomechanics model includes predicting a 3D distribution of in-situ stresses, pore pressure, and geomechanical properties, and wherein the 3D geomechanics model is configured to simulate in-situ stress changes due to drilling rock fragmentation.

A sixth feature, combinable with any of the previous or following features, where the operations further include performing diagenetic rock typing analysis for sweet spot identification and drilling rate of penetration for cost evaluation, and making decision for selecting drilling program and well placement based on the diagenetic rock typing analysis.

A seventh feature, combinable with any of the previous or following features, where the operations further include: extracting natural fracture information along a final well trajectory of the new well; simulating, using the 3D property modeling and natural fracture information, changes in in-situ stresses along the final well trajectory of the new well that are induced by drilling rock fragmentation; updating, based on the simulating, the in-situ stresses along the final well trajectory; and determining, based at least on the updated in-situ stresses along the final well trajectory, whether the natural fractures can shear slip or not after drilling the new well.

In a third implementation, a computer-implemented system includes one or more processors and a non-transitory computer-readable storage medium coupled to the one or more processors and storing programming instructions for execution by the one or more processors. The programming instructions instruct the one or more processors to perform operations including the following. Estimates of geomechanical properties for past-drilled wells are determined using planned well trajectories, formation tops, and well logs from the past-drilled wells. Image log processing is performed for the past-drilled wells using the planned well trajectories, the formation tops, and the well logs for the past-drilled wells. Three-dimensional (3D) property modeling of the past-drilled wells is performed using the estimates of geomechanical properties for the past-drilled wells. Natural fracture prediction (NFP) for the past-drilled wells is performed based at least on the image log processing. A 3D geomechanics model is generated using the 3D property modeling of the past-drilled wells and the NFP for the past-drilled wells. The NFP is contained in the 3D geomechanics model for hydraulic fracturing modeling and fracture stability analysis. A required breakdown pressure for a clustered-perforation hydraulic fracturing treatment for a new well is determined using the 3D geomechanics model. A determination is made whether underbalanced coiled tubing drilling or conventional drilling with hydraulic fracturing is to be used in a drilling operation of the new well. The determination is made using the required breakdown pressure for the clustered-perforation hydraulic fracturing treatment for the new well.

The foregoing and other described implementations can each, optionally, include one or more of the following features:

A first feature, combinable with any of the following features, where the estimates of geomechanical properties for the past-drilled wells include Young's modulus, Poisson ratio, Biot coefficient, unconfined compressive strength, and tensile strength.

A second feature, combinable with any of the previous or following features, where performing the image log processing for the past-drilled wells includes determining fracture intensity and maximum horizontal stress orientation.

A third feature, combinable with any of the previous or following features, where performing the 3D property modeling results in a 3D distribution of Young's modulus, Poisson ratio, Biot coefficient, unconfined compressive strength, and tensile strength, and wherein property modeling includes a process of filling cells of a 3D grid with one or both of discrete and continuous properties.

Implementations of the subject matter and the functional operations described in this specification can be implemented in digital electronic circuitry, in tangibly embodied computer software or firmware, in computer hardware, including the structures disclosed in this specification and their structural equivalents, or in combinations of one or more of them. Software implementations of the described subject matter can be implemented as one or more computer programs. Each computer program can include one or more modules of computer program instructions encoded on a tangible, non-transitory, computer-readable computer-storage medium for execution by, or to control the operation of, data processing apparatus. Alternatively, or additionally, the program instructions can be encoded in/on an artificially generated propagated signal. For example, the signal can be a machine-generated electrical, optical, or electromagnetic signal that is generated to encode information for transmission to a suitable receiver apparatus for execution by a data processing apparatus. The computer-storage medium can be a machine-readable storage device, a machine-readable storage substrate, a random or serial access memory device, or a combination of computer-storage mediums.

The terms “data processing apparatus,” “computer,” and “electronic computer device” (or equivalent as understood by one of ordinary skill in the art) refer to data processing hardware. For example, a data processing apparatus can encompass all kinds of apparatuses, devices, and machines for processing data, including by way of example, a programmable processor, a computer, or multiple processors or computers. The apparatus can also include special purpose logic circuitry including, for example, a central processing unit (CPU), a field-programmable gate array (FPGA), or an application-specific integrated circuit (ASIC). In some implementations, the data processing apparatus or special purpose logic circuitry (or a combination of the data processing apparatus or special purpose logic circuitry) can be hardware- or software-based (or a combination of both hardware- and software-based). The apparatus can optionally include code that creates an execution environment for computer programs, for example, code that constitutes processor firmware, a protocol stack, a database management system, an operating system, or a combination of execution environments. The present disclosure contemplates the use of data processing apparatuses with or without conventional operating systems, such as LINUX, UNIX, WINDOWS, MAC OS, ANDROID, or IOS.

A computer program, which can also be referred to or described as a program, software, a software application, a module, a software module, a script, or code, can be written in any form of programming language. Programming languages can include, for example, compiled languages, interpreted languages, declarative languages, or procedural languages. Programs can be deployed in any form, including as stand-alone programs, modules, components, subroutines, or units for use in a computing environment. A computer program can, but need not, correspond to a file in a file system. A program can be stored in a portion of a file that holds other programs or data, for example, one or more scripts stored in a markup language document, in a single file dedicated to the program in question, or in multiple coordinated files storing one or more modules, sub-programs, or portions of code. A computer program can be deployed for execution on one computer or on multiple computers that are located, for example, at one site or distributed across multiple sites that are interconnected by a communication network. While portions of the programs illustrated in the various figures may be shown as individual modules that implement the various features and functionality through various objects, methods, or processes, the programs can instead include a number of sub-modules, third-party services, components, and libraries. Conversely, the features and functionality of various components can be combined into single components as appropriate. Thresholds used to make computational determinations can be statically, dynamically, or both statically and dynamically determined.

The methods, processes, or logic flows described in this specification can be performed by one or more programmable computers executing one or more computer programs to perform functions by operating on input data and generating output. The methods, processes, or logic flows can also be performed by, and apparatus can also be implemented as, special purpose logic circuitry, for example, a CPU, an FPGA, or an ASIC.

Computers suitable for the execution of a computer program can be based on one or more of general and special purpose microprocessors and other kinds of CPUs. The elements of a computer are a CPU for performing or executing instructions and one or more memory devices for storing instructions and data. Generally, a CPU can receive instructions and data from (and write data to) a memory.

Graphics processing units (GPUs) can also be used in combination with CPUs. The GPUs can provide specialized processing that occurs in parallel to processing performed by CPUs. The specialized processing can include artificial intelligence (AI) applications and processing, for example. GPUs can be used in GPU clusters or in multi-GPU computing.

A computer can include, or be operatively coupled to, one or more mass storage devices for storing data. In some implementations, a computer can receive data from, and transfer data to, the mass storage devices including, for example, magnetic, magneto-optical disks, or optical disks. Moreover, a computer can be embedded in another device, for example, a mobile telephone, a personal digital assistant (PDA), a mobile audio or video player, a game console, a global positioning system (GPS) receiver, or a portable storage device such as a universal serial bus (USB) flash drive.

Computer-readable media (transitory or non-transitory, as appropriate) suitable for storing computer program instructions and data can include all forms of permanent/non-permanent and volatile/non-volatile memory, media, and memory devices. Computer-readable media can include, for example, semiconductor memory devices such as random access memory (RAM), read-only memory (ROM), phase change memory (PRAM), static random access memory (SRAM), dynamic random access memory (DRAM), erasable programmable read-only memory (EPROM), electrically erasable programmable read-only memory (EEPROM), and flash memory devices. Computer-readable media can also include, for example, magnetic devices such as tape, cartridges, cassettes, and internal/removable disks. Computer-readable media can also include magneto-optical disks and optical memory devices and technologies including, for example, digital video disc (DVD), CD-ROM, DVD+/−R, DVD-RAM, DVD-ROM, HD-DVD, and BLU-RAY. The memory can store various objects or data, including caches, classes, frameworks, applications, modules, backup data, jobs, web pages, web page templates, data structures, database tables, repositories, and dynamic information. Types of objects and data stored in memory can include parameters, variables, algorithms, instructions, rules, constraints, and references. Additionally, the memory can include logs, policies, security or access data, and reporting files. The processor and the memory can be supplemented by, or incorporated into, special purpose logic circuitry.

Implementations of the subject matter described in the present disclosure can be implemented on a computer having a display device for providing interaction with a user, including displaying information to (and receiving input from) the user. Types of display devices can include, for example, a cathode ray tube (CRT), a liquid crystal display (LCD), a light-emitting diode (LED), and a plasma monitor. Display devices can include a keyboard and pointing devices including, for example, a mouse, a trackball, or a trackpad. User input can also be provided to the computer through the use of a touchscreen, such as a tablet computer surface with pressure sensitivity or a multi-touch screen using capacitive or electric sensing. Other kinds of devices can be used to provide for interaction with a user, including to receive user feedback including, for example, sensory feedback including visual feedback, auditory feedback, or tactile feedback. Input from the user can be received in the form of acoustic, speech, or tactile input. In addition, a computer can interact with a user by sending documents to, and receiving documents from, a device that the user uses. For example, the computer can send web pages to a web browser on a user's client device in response to requests received from the web browser.

The term “graphical user interface,” or “GUI,” can be used in the singular or the plural to describe one or more graphical user interfaces and each of the displays of a particular graphical user interface. Therefore, a GUI can represent any graphical user interface, including, but not limited to, a web browser, a touch-screen, or a command line interface (CLI) that processes information and efficiently presents the information results to the user. In general, a GUI can include a plurality of user interface (UI) elements, some or all associated with a web browser, such as interactive fields, pull-down lists, and buttons. These and other UI elements can be related to or represent the functions of the web browser.

Implementations of the subject matter described in this specification can be implemented in a computing system that includes a back-end component, for example, as a data server, or that includes a middleware component, for example, an application server. Moreover, the computing system can include a front-end component, for example, a client computer having one or both of a graphical user interface or a Web browser through which a user can interact with the computer. The components of the system can be interconnected by any form or medium of wireline or wireless digital data communication (or a combination of data communication) in a communication network. Examples of communication networks include a local area network (LAN), a radio access network (RAN), a metropolitan area network (MAN), a wide area network (WAN), Worldwide Interoperability for Microwave Access (WIMAX), a wireless local area network (WLAN) (for example, using 802.11 a/b/g/n or 802.20 or a combination of protocols), all or a portion of the Internet, or any other communication system or systems at one or more locations (or a combination of communication networks). The network can communicate with, for example, Internet Protocol (IP) packets, frame relay frames, asynchronous transfer mode (ATM) cells, voice, video, data, or a combination of communication types between network addresses.

The computing system can include clients and servers. A client and server can generally be remote from each other and can typically interact through a communication network. The relationship of client and server can arise by virtue of computer programs running on the respective computers and having a client-server relationship.

Cluster file systems can be any file system type accessible from multiple servers for read and update. Locking or consistency tracking may not be necessary since the locking of exchange file system can be done at the application layer. Furthermore, Unicode data files can be different from non-Unicode data files.

While this specification contains many specific implementation details, these should not be construed as limitations on the scope of what may be claimed, but rather as descriptions of features that may be specific to particular implementations. Certain features that are described in this specification in the context of separate implementations can also be implemented, in combination, in a single implementation. Conversely, various features that are described in the context of a single implementation can also be implemented in multiple implementations, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results. In certain circumstances, multitasking or parallel processing (or a combination of multitasking and parallel processing) may be advantageous and performed as deemed appropriate.

Moreover, the separation or integration of various system modules and components in the previously described implementations should not be understood as requiring such separation or integration in all implementations. It should be understood that the described program components and systems can generally be integrated together in a single software product or packaged into multiple software products.

Accordingly, the previously described example implementations do not define or constrain the present disclosure. Other changes, substitutions, and alterations are also possible without departing from the spirit and scope of the present disclosure.

Furthermore, any claimed implementation is considered to be applicable to at least a computer-implemented method; a non-transitory, computer-readable medium storing computer-readable instructions to perform the computer-implemented method; and a computer system including a computer memory interoperably coupled with a hardware processor configured to perform the computer-implemented method or the instructions stored on the non-transitory, computer-readable medium.

What is claimed is:

1. A computer-implemented method, comprising:
determining, using planned well trajectories, formation tops, and well logs from past-drilled wells, estimates of geomechanical properties for the past-drilled wells;
performing, using the planned well trajectories, the formation tops, and the well logs for the past-drilled wells, image log processing for the past-drilled wells, including fracture types, orientations, intensity and maximum horizontal stress orientation;
performing, using the estimates of geomechanical properties for the past-drilled wells, three-dimensional (3D) property modeling;
performing, based at least on the image log processing, natural fracture prediction (NFP) for the domain covering the past-drilled wells;
generating, using the 3D property modeling and the NFP, a 3D geomechanics model, wherein the NFP is contained in the 3D geomechanics model for hydraulic fracturing modeling and fracture stability analysis;
determining, using the 3D geomechanics model, required breakdown pressure for a clustered-perforation hydraulic fracturing treatment for a new well; and
determining, using the required breakdown pressure for the clustered-perforation hydraulic fracturing treatment for the new well, whether underbalanced coiled tubing drilling or conventional drilling with hydraulic fracturing is to be used in a drilling operation of the new well.

2. The computer-implemented method of claim 1, wherein the estimates of geomechanical properties for the past-drilled wells include Young's modulus, Poisson ratio, Biot coefficient, unconfined compressive strength, and tensile strength.

3. The computer-implemented method of claim 1, wherein performing the image log processing for the past-drilled wells includes determining fracture types, orientations, intensity and maximum horizontal stress orientation.

4. The computer-implemented method of claim 1, wherein performing the 3D property modeling results in a 3D distribution of Young's modulus, Poisson ratio, Biot coefficient, unconfined compressive strength, and tensile strength, and wherein property modeling includes a process of filling cells of a 3D grid with one or both of discrete and continuous properties.

5. The computer-implemented method of claim 1, wherein performing the NFP for a field having past-drilled wells includes a discrete fracture network and results in a distribution of discrete natural fractures in terms of sizes and orientations, including azimuth and dip).

6. The computer-implemented method of claim 1, wherein generating the 3D geomechanics model includes predicting a 3D distribution of in-situ stresses, pore pressure, and geomechanical properties, and wherein the 3D geomechanics model is configured to simulate in-situ stress changes due to drilling rock fragmentation.

7. The computer-implemented method of claim 1, further comprising performing diagenetic rock typing analysis for sweet spot identification and drilling rate of penetration for cost evaluation, and making decision for selecting drilling program and well placement based on the diagenetic rock typing analysis.

8. The computer-implemented method of claim 1, further comprising:
extracting natural fracture information along a final well trajectory of the new well;
simulating, using the 3D property modeling and natural fracture information, changes in in-situ stresses along the final well trajectory of the new well that are induced by drilling rock fragmentation;
updating, based on the simulating, the in-situ stresses along the final well trajectory; and
determining, based at least on the updated in-situ stresses along the final well trajectory, whether the natural fractures can shear slip or not after drilling the new well.

9. A non-transitory, computer-readable medium storing one or more instructions executable by a computer system to perform operations comprising:
determining, using planned well trajectories, formation tops, and well logs from past-drilled wells, estimates of geomechanical properties for the past-drilled wells;
performing, using the planned well trajectories, the formation tops, and the well logs for the past-drilled wells, image log processing for the past-drilled wells, including fracture types, orientations and intensity, and maximum horizontal stress orientation;
performing, using the estimates of geomechanical properties for the past-drilled wells, three-dimensional (3D) property modeling;
performing, based at least on the image log processing, natural fracture prediction (NFP) for the domain covering the past-drilled wells;
generating, using the 3D property modeling and the NFP, a 3D geomechanics model, wherein the NFP is contained in the 3D geomechanics model for hydraulic fracturing modeling and fracture stability analysis;
determining, using the 3D geomechanics model, required breakdown pressure for a clustered-perforation hydraulic fracturing treatment for a new well; and
determining, using the required breakdown pressure for the clustered-perforation hydraulic fracturing treatment for the new well, whether underbalanced coiled tubing drilling or conventional drilling with hydraulic fracturing is to be used in a drilling operation of the new well.

10. The non-transitory, computer-readable medium of claim 9, wherein the estimates of geomechanical properties for the past-drilled wells include Young's modulus, Poisson ratio, Biot coefficient, unconfined compressive strength, and tensile strength.

11. The non-transitory, computer-readable medium of claim 9, wherein performing the image log processing for the past-drilled wells includes determining fracture intensity and maximum horizontal stress orientation.

12. The non-transitory, computer-readable medium of claim 9, wherein performing the 3D property modeling results in a 3D distribution of Young's modulus, Poisson ratio, Biot coefficient, unconfined compressive strength, and tensile strength, and wherein property modeling includes a process of filling cells of a 3D grid with one or both of discrete and continuous properties.

13. The non-transitory, computer-readable medium of claim 9, wherein performing the NFP for a field having past-drilled wells includes a discrete fracture network and results in a distribution of discrete natural fractures in terms of sizes and orientations, including azimuth and dip).

14. The non-transitory, computer-readable medium of claim 9, wherein generating the 3D geomechanics model includes predicting a 3D distribution of in-situ stresses, pore pressure, and geomechanical properties, and wherein the 3D geomechanics model is configured to simulate in-situ stress changes due to drilling rock fragmentation.

15. The non-transitory, computer-readable medium of claim 9, the operations further comprising performing diagenetic rock typing analysis for sweet spot identification and drilling rate of penetration for cost evaluation, and making decision for selecting drilling program and well placement based on the diagenetic rock typing analysis.

16. The non-transitory, computer-readable medium of claim 9, the operations further comprising:
extracting natural fracture information along a final well trajectory of the new well;
simulating, using the 3D property modeling and natural fracture information, changes in in-situ stresses along the final well trajectory of the new well that are induced by drilling rock fragmentation;
updating, based on the simulating, the in-situ stresses along the final well trajectory; and
determining, based at least on the updated in-situ stresses along the final well trajectory, whether the natural fractures can shear slip or not after drilling the new well.

17. A computer-implemented system, comprising:
one or more processors; and
a non-transitory computer-readable storage medium coupled to the one or more processors and storing programming instructions for execution by the one or more processors, the programming instructions instructing the one or more processors to perform operations comprising:
determining, using planned well trajectories, formation tops, and well logs from past-drilled wells, estimates of geomechanical properties for the past-drilled wells;
performing, using the planned well trajectories, the formation tops, and the well logs for the past-drilled wells, image log processing for the past-drilled wells, including fracture types, orientations, intensity and maximum horizontal stress orientation;
performing, using the estimates of geomechanical properties for the past-drilled wells, three-dimensional (3D) property modeling;
performing, based at least on the image log processing, natural fracture prediction (NFP) for the domain covering the past-drilled wells;
generating, using the 3D property modeling of the past-drilled wells and the NFP for the past-drilled wells, a 3D geomechanics model, wherein the NFP is contained in the 3D geomechanics model for hydraulic fracturing modeling and fracture stability analysis;
determining, using the 3D geomechanics model, required breakdown pressure for a clustered-perforation hydraulic fracturing treatment for a new well; and
determining, using the required breakdown pressure for the clustered-perforation hydraulic fracturing treatment for the new well, whether underbalanced coiled tubing drilling or conventional drilling with hydraulic fracturing is to be used in a drilling operation of the new well.

18. The computer-implemented system of claim 17, wherein the estimates of geomechanical properties for the past-drilled wells include Young's modulus, Poisson ratio, Biot coefficient, unconfined compressive strength, and tensile strength.

19. The computer-implemented system of claim 17, wherein performing the image log processing for the past-drilled wells includes determining fracture types, orientations, intensity and maximum horizontal stress orientation.

20. The computer-implemented system of claim 17, wherein performing the 3D property modeling results in a 3D distribution of Young's modulus, Poisson ratio, Biot coefficient, unconfined compressive strength, and tensile strength, and wherein property modeling includes a process of filling cells of a 3D grid with one or both of discrete and continuous properties.
